(19) United States
(12) Patent Application Publication
(10) Pub. No.: US 2023/0118326 A1
(43) Pub. Date: Apr. 20, 2023

(54) VISIBLE WAVELENGTH LED-BASED FIBER LINK

(71) Applicants: Bardia Pezeshki, Mountain View, CA (US); Alexander Tselikov, Mountain View, CA (US); Robert Kalman, Mountain View, CA (US)

(72) Inventors: Bardia Pezeshki, Mountain View, CA (US); Alexander Tselikov, Mountain View, CA (US); Robert Kalman, Mountain View, CA (US)

(21) Appl. No.: 18/047,501

(22) Filed: Oct. 18, 2022

Related U.S. Application Data
(60) Provisional application No. 63/256,767, filed on Oct. 18, 2021.

(51) Int. Cl. G02B 6/43; G02B 6/42; H01L 25/075

(52) U.S. Cl. CPC G02B 6/43; G02B 6/4249; H01L 25/0753; H01L 33/32

(57) ABSTRACT

An optical data link using an array of GaN based microLEDs, plastic optical fibers, and photodetectors with lateral structures is disclosed. The array of microLEDs may utilize a wavelength range that reduces transmission loss and may be driven at an optimal current density to achieve the desired radiative efficiency. The structure of the microLED may be in the form of a p-n junction and utilize p-doping in the recombination region near the n-region. The optical data link may also be bidirectional.

### CROSS-REFERENCE TO RELATED APPLICATIONS

This application claims the benefit of U.S. Provisional Patent Application No. 63/256,767, filed on Oct. 18, 2021, the disclosure of which is incorporated by reference herein.

### FIELD OF THE INVENTION

The present invention relates generally to fiber optic data links, and more particularly to fiber optic data links using LEDs and plastic optical fiber.

### BACKGROUND OF THE INVENTION

Today, high speed data links longer than a few meters are almost all fiber optics based, while data links shorter than a few meters are electrical. The reason is the impairment of copper-based electrical links get worse with distance, while converting electrical signals to optical and back again is relatively complex and expensive. So for shorter distances, links remain electrical, while for longer distances, optical offers advantages. The boundary between the two is at a few meters when lane speeds are a few Gb/s. For links longer than a few meters, optics offers advantages because inexpensive high-speed optoelectronic components are generally available, optical fiber is low loss at these wavelengths, and fiber optic links are generally less prone to distortion and interference than electrical links.

Typical laser sources for relatively short distance (10 m<distance<300 m) and low-cost fiber optic links use vertical cavity surface-emitting lasers (VCSELs) that can be modulated individually or in arrays and are coupled into multimode fibers. These fibers typically have a core diameter of about 50 μm. For array applications, ribbons of such multi-mode fibers are used. VCSELs at 780 nm, 850 nm, and up to about 1 μm wavelength can be used with silicon detectors that are relatively high speed and inexpensive at diameters of up to 50 μm. Edge-emitting Fabry-Perot or distributed feedback (DFB) lasers can also be used, but typically are more expensive and require more drive current. These waveguide-based lasers typically run at a wavelength of 1.3 μm or 1.55 μm. All these fiber optic links are typically used for link lengths greater than a few meters.

At shorter distance less than a few meters, electrical interconnects over metallic cables remain dominant, on account of cost and simplicity. The impairments are not as severe at shorter distances and copper cabling is simple and relatively inexpensive. Furthermore, for many applications, the reliability and temperature performance of optoelectronic components is inferior to that of electrical interconnects. For example, in automotive applications, where the operating temperature requirements can be over 100° C., it is difficult to use lasers whose performance and lifetime degrades dramatically at higher temperature. Furthermore, even low cost VCSELs are costly and complex compared to electrical interconnects, and the relatively tight 50 μm core size of multimode fiber requires a somewhat sophisticated assembly process. Lasers are typically grown on GaAs or InP substrates and must be packaged separately from the silicon electronic drivers, detectors or amplifiers, also adding cost. Thus, almost all high-speed electrical links below a few meters remain electrical.

Plastic optical fiber (POF) links have found a small niche in the short distance space using conventional red LEDs using InGaAlP materials grown on GaAs as transmitters. Plastic optical fiber is very cheap, and for large core diameters (˜0.5 mm), it is easy to attach to LED sources. However, the modulation speed of LEDs is generally limited to below 1 Gb/s. The large area of the fiber also generally requires larger detectors, which means that the capacitance of the detector is high and the optical receivers therefore have relatively low bandwidths.

Thus, using established technologies, it is not possible to get very low-cost optical links that are cost-effective and robust at very short distances, and high speed data links of a few meters or less remain electrical. This includes links between servers and switches within a rack in a datacenter, USB or cables for computer interfaces, electrical connections across circuit boards, connections in automotive environments, and data links to high-speed image sensors and similar applications.

### BRIEF SUMMARY OF THE INVENTION

Some aspects of the invention provide extremely low-cost high-speed data links of a few meters using optical technology, optical technology that is robust and simple in some embodiments. Some aspects of the invention provide data links to many Gb/s per lane at very low-cost component and packaging cost.

Some aspects of the invention provide an optical data link making use of at least one microLED generating light in the visible spectrum, a photodetector with a lateral structure for detecting the light, and a plastic optical fiber with a core diameter in the range of 100 μm-1000 μm for passing the light from the at least one microLED to the photodetector. In some embodiments the at least one microLED is an array of microLEDs. In some embodiments the microLEDs are operated at a data rate greater than 1 Gb/s. In some embodiments the microLEDs include a p-region, an n-region, and a recombination region including quantum wells between the p-region and the n-region. Some embodiments include p-doping in the recombination region near the n-region. In some embodiments, the at least one microLED is comprised of GaN. In some embodiments the plastic optical fiber has a core diameter of about 0.50 mm, for example between 0.4 and 0.5 mm.

Some aspects of the invention provide an optical data link with an array of microLEDs, connected in parallel, for generating light, to carry data, in a wavelength range between 420 nm and 500 nm, inclusive, the microLEDs of the array of microLEDs having a 3 dB modulation bandwidth greater than 1 Gb/s when driven with a current density of 30 A/cm\hat{ }2, a plastic optical fiber with a core diameter in the range of 100 μm-1000 μm for carrying the light to a receiver, the receiver including a photodetector with a lateral structure. In some embodiments the microLEDs each have a diameter of 50 μm or less. In some embodiments the lateral structure of the photodetector extends beyond a diameter of the core of the plastic optical fiber. In some embodiments the array of microLEDs is within an outline of a lateral structure of a further photodetector, and a further array of microLEDs are within an outline of the lateral structure of the photodetector, providing a duplex optical data link over a single fiber core. In some embodiments driver circuitry for the microLEDs is configured to drive the microLEDs at a current within a range of 10 to 100 A/cm\hat{ }2. In some embodiments the microLEDs have a 3 dB modulation bandwidth greater than 1 Gb/s when driven with a current density in a range of 10 A/cm\hat{ }2 to 60 A/cm\hat{ }2.

Some embodiments provide an optical data link comprising: an array of microLEDs, comprised of GaN, connected in parallel, for generating light, to carry data, in a wavelength range between 420 nm and 500 nm, inclusive, the microLEDs of the array of microLEDs having a 3 dB bandwidth greater than 1 Gb/s when driven with a current density of about 30 A/cm\hat{ }2; a receiver including a photodetector with a lateral structure; and a plastic optical fiber with a core diameter in the range of 100 μm-1000 μm for carrying the light to the receiver. In some embodiments the microLEDs each have a diameter of 20 microns or less. In some embodiments the lateral structure of the photodetector extends beyond the diameter of the core of the plastic optical fiber. In some embodiments the array of microLEDs is within an outline of a lateral structure of a further photodetector, and a further array of microLEDs are within an outline of the lateral structure of the photodetector, providing a duplex optical data link. In some embodiments the microLEDs include a n-region, a p-region, and a quantum well region between the n-region and the p-region, with a side of the quantum well region closest to the n-region p-doped. Some embodiments further comprise a silicon substrate, driver circuitry for driving the array of microLEDs and wherein the receiver includes an amplifier for amplifying signals from the photodetector, with the driver circuitry, amplifier, and photodetector in the silicon substrate and the array of microLEDs on the silicon substrate. In some embodiments the receiver does not include equalization circuitry for processing of signals after reception from the plastic optical fiber. In some embodiments the plastic optical fiber has a length of less than 10 meters. In some embodiments the plastic optical fiber has a length between 1 and 5 meters.

Some embodiments provide an optical data link, comprising: at least one microLED generating light in the visible spectrum; a photodetector with a lateral structure for detecting the light; and a plastic optical fiber with a core diameter in the range of 100 μm-1000 μm for passing the light from the at least one microLED to the photodetector. In some embodiments the at least one microLED is an array of microLEDs electrically connected to drive circuitry in parallel. In some embodiments the microLEDs include a p-region, an n-region, and a recombination region including quantum wells between the p-region and the n-region, with p-doping in the recombination region near the n-region. In some embodiments the microLEDs are comprised of GaN. In some embodiments the plastic optical fiber has a core diameter of about 0.50 mm. In some embodiments the plastic optical fiber has a core diameter between 0.4 and 0.5 mm.

These and other aspects of the invention are more fully comprehended upon review of this disclosure.

### BRIEF DESCRIPTION OF THE FIGURES

FIG. 1 is a graph of an optical transmission loss of PMMA based plastic optical fiber, in accordance with aspects of the invention.

FIGS. 2A-B are a vertical cross section structure and band-diagram of an LED optimized for high speed at low current density, in accordance with aspects of the invention.

FIG. 3 is a graph of the quantum efficiency and modulation bandwidth of LEDs optimized for speed at low current densities, in accordance with aspects of the invention.

FIGS. 4A-B are a cross section and top view diagrams of a lateral detector device, in accordance with aspects of the invention.

FIG. 5 is a diagram of a dual fiber system using LED and detectors to create a bidirectional link, in accordance with aspects of the invention.

FIG. 6 is a diagram of a transceiver, in accordance with aspects of the invention.

FIG. 7 is a diagram with LEDs interspersed within a photodetector, allowing for a single fiber bidirectional link (half-duplex), in accordance with aspects of the invention.

### DETAILED DESCRIPTION

Recently there has been some interest in LED-based optical transmitters that are faster and use GaN technology. As previously mentioned, commercial LED-based links generally operate at much less than 1 Gb/s per lane. They typically run at a wavelength near 650 nm in a window where some plastic optical fibers, made from materials such as PMMA, have quite low attenuation. These 650 nm LEDs are made in the AlGaInP material system, grown on GaAs substrates.

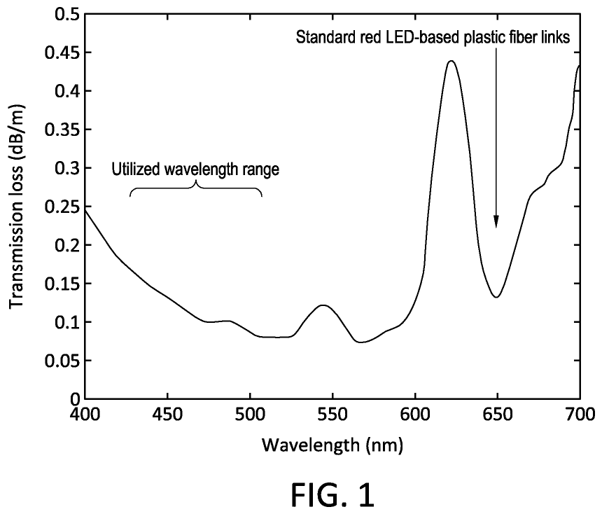

FIG. 1 shows a graph of an optical transmission loss of a PMMA based plastic optical fiber. The conventional window at 650 nm with red LEDs has a loss of about 0.12 dB/m. The loss peaks at shorter wavelengths, but then drops again, the fiber becoming transparent below about 580 nm. There is also another wider window of operation where the fiber is relatively transparent between about 420 nm and 580 nm, with loss below 0.2 dB/m. Embodiments herein may generally use a wavelength window in the 420 nm-500 nm range.

Recently GaN LEDs have been developed for lighting applications, and operate in the shorter wavelength visible part of the spectrum and have shown speeds up to 1 Gb/s in on-off modulation. Though not commercial, there have been reports of LED based data links using this newer GaN material system. In general the devices are driven very hard at many thousands of amps per centimeter square to get the high speeds. By operating at shorter wavelengths, they can use the second wider window in the blue-green range of 420 nm and 580 nm. More recently some structures have shown higher speed modulation of GaN LEDs up to 10 Gb/s. But once again, these LEDs operate at very high current densities.

Some aspects of the invention provide high speed LED link that is well suited to large diameter plastic optical fiber and operates at shorter wavelengths. Some embodiments use a short wavelength LED that can operate at high speeds, for example over 1 Gb/s, at low current densities, for example 30 A/cm\hat{ }2. For some embodiments this makes it possible to have a large area LED transmitter that generates enough light to implement links with low bit error ratio at low current densities, where the devices are extremely reliable. Furthermore, some embodiments use a lateral p-i-n photodetector that has a low capacitance per unit area, and can thus be made large while also being capable of high speed operation. Large high-speed photodetectors enable use of large diameter plastic optical fiber (core size in the range of 100 μm to 1000 μm). Such large core fibers have greatly relaxed mechanical alignment tolerances for coupling to optical transmitters and receivers, enabling extremely low cost packaging. Such links using large core plastic optical fiber can operate at >1 Gb/s and also tolerate extreme temperatures.

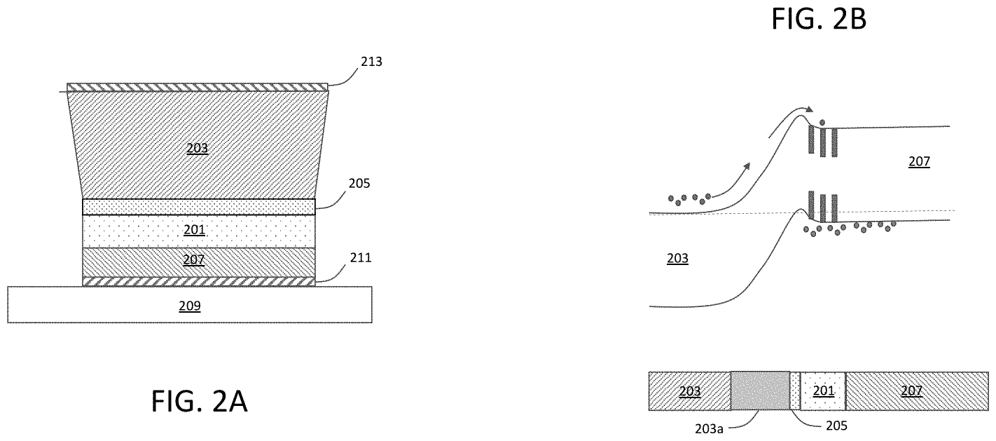

FIGS. 2A-B show a vertical cross section structure and a band-diagram of an LED for optimized high speed at low current density. In a normal LED structure the quantum wells where the recombination occurs are nominally undoped and placed in the center of a p-n junction. Carriers are injected into this depletion region from the n-side and the p-side. Electrons and holes find each other and recombine. However, this bipolar injection means that at low current densities, there are fewer electrons and holes and the carrier lifetime is long. Once the injection levels are high enough, then recombination time decreases as most recombination mechanisms depend on the carrier density.

In some embodiments, and as shown in FIG. 2A, the side of the quantum wells close to the n-region 203 is highly p-doped, which may be referred to as a p-doped “spike” 205. This highly doped region is mostly depleted in the junction and the quantum wells are placed in an undoped region 201 sandwiched between the p-doped spike 205 and the p-doped GaN 207. The band diagram of FIG. 2B also shows a portion 203a of the n-region nearest the p-doped spike being a depleted n-region. Given the high p-doping on both sides of the quantum wells, there is a very high hole density in these quantum wells. In GaN, the mobility of the holes is much less than that of electrons. So despite the high doping in the p-region, it is still the electrons that generally flow into the junction. For the most part they transit through the p-spike and recombine in the undoped quantum wells beyond. Since there is already a high p-doping level in these quantum wells, the carrier recombination is rapid, even at low currents. In some embodiments, the acceptor dopant (typically Mg) is mostly kept out of the wells, so scattering from defects is low and excitonic and Coulombic enhancement is increased. This leads to the electrons finding the holes quickly and a short carrier lifetime, which supports high modulation bandwidths. In some embodiments, the p-spike doping concentration is approximately 10¹⁹/cm³.

This LED structure is typically grown on sapphire. In some embodiments, the devices are transferred to another “target” substrate 209 using a process such as laser lift-off (LLO). In some embodiments, the device is turned “upside down” during the transfer process so the p-type layer is on the “bottom” next to the target substrate. In some embodiments, the electrical connection to the p-side of the diode is optically reflective so also acts as a back mirror 211 to increase the efficiency of light extraction from the LED. In some embodiments, there is a transparent electrical contact 213 such as ITO deposited on the n-side to make electrical contact to the n-side of the diode.

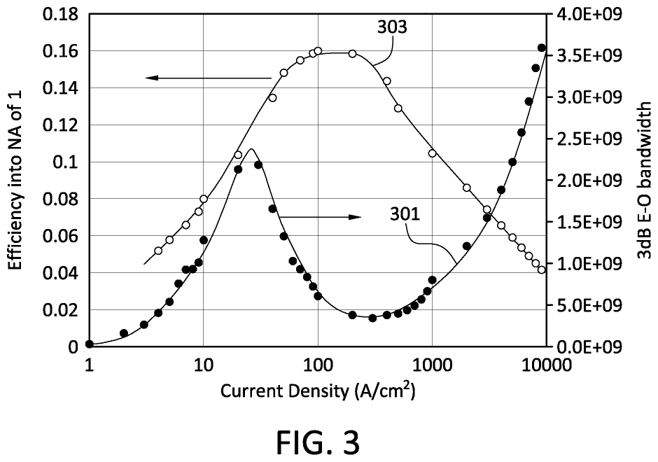

FIG. 3 is a graph of the quantum efficiency and 3 dB electro-optical modulation bandwidth of LEDs optimized for speed at low current densities, showing the effect of the p-doped spike structure described herein. The LEDs corresponding to FIG. 3 may operate at a wavelength range around 430 nm. The first line 301 is the speed of the diode, as measured by the 3 dB modulation bandwidth. At low current densities, the speed of the diode rapidly increases and peaks at about 30 A/cm\hat{ }2. This is when a relatively low density of electrons is injected and recombines in the quantum wells where there is a high density of holes. As the current density is further increased, the modulation bandwidth decreases as the injected electrons begin to interact with each other, causing scattering and shielding the excitonic effects. At higher injection levels, both holes and electrons increase in density and carrier, which increases both the radiative recombination rate and the nonradiative recombination rate due to Auger recombination and other effects. Also shown in the plot is the radiative efficiency 303 of the diode. At very low levels, the diode is inefficient, as there is considerable SRH (Schottky Reed Hall) recombination due to unsaturated traps. As the current density increases, these traps become saturated, and we have more radiative recombination that boosts efficiency. Finally, the efficiency drops at high currents due to non-radiative Auger recombination. Note that for a given speed the efficiency is higher by almost a factor of 2 at the low current density peak than at the high current density mode dominated by Auger recombination.

With a high speed peak at a 3 dB roll-off frequency of 2.5 GHz, as shown in FIG. 3, it is possible to run links at 5 Gb/s or even faster with equalization. In many embodiments, however, no equalization is performed on the signal, either by the transmitter and/or the receiver, and one or both of the transmitter and the receiver may not include equalization circuitry for processing of signals prior to transmission over the optical link or after reception of the signals from the optical link. With the proper optics, in some embodiments an LED drive current of about 1 mA generates sufficient light that an acceptable bit error ratio BER (in some embodiments, <=1e-12) can be achieved at the receiver. 1 mA at a current density of 30 A/cm\hat{ }2 gives us a device diameter of about 80 μm for the LED. Note that for a larger desired power level, one could use a larger LED. In most embodiments, though the LED size is substantially smaller than the nominal plastic optical fiber core diameter so that the LED's light can be efficiently coupled into the plastic optical fiber core.

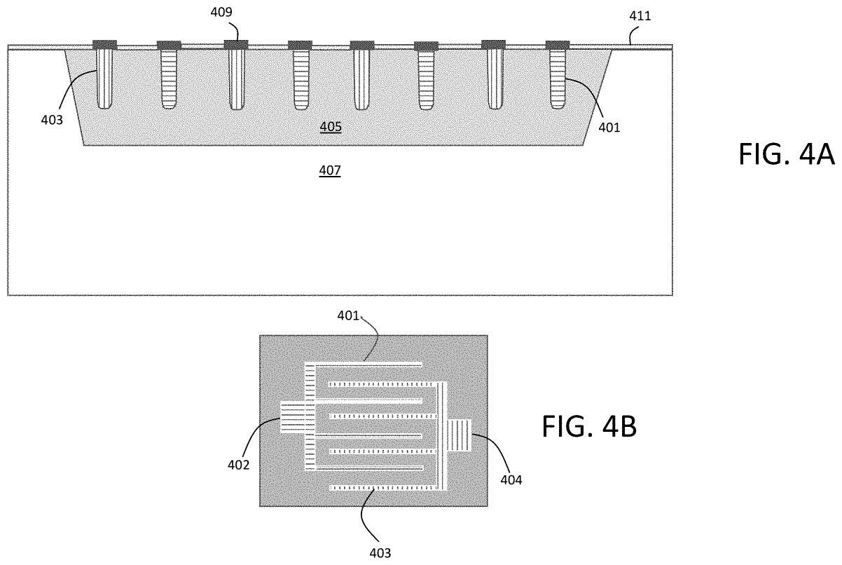

FIGS. 4A-B show cross section and top view diagrams of a lateral detector device. Such structures may have much lower capacitance per unit area than standard vertical p-i-n devices. Since blue light is very efficiently absorbed in silicon, in some embodiments of a GaN LED-based link, a “lateral” photodetector structure with very low capacitance per unit area is used at the receiver. This allows their use with large diameter fibers that are low cost and easy to package. FIG. 4A specifically shows the lateral structure of an example large area photodetector. The photodetector structure comprises alternating p-type and n-type fingers 401 and 403, respectively, separated by low-doped (ideally intrinsic) silicon, where all n-type fingers 403 are electrically connected to each other to form the photodetector n-contact 404, and all p-type fingers 401 are electrically connected to each other to form the photodetector p-contact 402. The low-doped silicon may have an n-well 405 containing the p-type and n-type fingers, where the n-well may be contained in a p-type silicon wafer 407. In some embodiments, the portion of the p-type and n-type fingers on the photodetector top surface may have a silicide or metal 409 covering. Additionally, the top surface of the photodetector, other than over the fingers, may have a surface oxide layer 411. The fingers are formed by dopant diffusions. Given the absorption depth of only about 0.15 microns in silicon for short wavelength light (<450 nm), a finger diffusion depth of 0.5 μm would give about 90% light absorption by the Si, further limited only by the shadowing of the fingers. With a typical finger spacing of 5 μm, such a structure with total dimension 0.5 mm×0.5 mm gives a capacitance of 0.4 pF. This gives an RC-limited 3 dB bandwidth of almost 10 GHz in a 50 Ohm transmission line.

Compared to a standard “vertical” photodetector structure where the p-n junction is along the surface normal direction, the lateral structure described herein provides far lower capacitance per unit area, and thus far higher 3 dB bandwidth, for a given area (in cases where bandwidth is limited by the capacitance of the photodetector). A more common “vertical” photodetector structure comprises a stack of p-type, intrinsic, and n-type Si layers; with a 5 μm thick intrinsic region, such a photodetector would be expected to have the same voltage/speed characteristics as a lateral photodetector with fingers separated by 5 μm, but would have a capacitance per unit area that is approximately 10 times higher than the lateral photodetector structure. Thus, under RC-limited bandwidth conditions, such a vertical photodetector would be expected to have only 1/10^{th} the bandwidth of the comparable lateral photodetector.

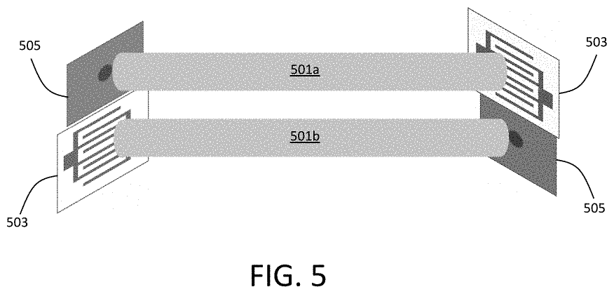

FIG. 5 shows a diagram of a dual fiber system using LED and detectors to create a bidirectional link. By using the large area LEDs and photodetectors on each side with dual fibers, a bidirectional link can be established. In some embodiments, a bidirectional link is fabricated with two fibers 501a,b, where each fiber carries light in one direction, opposite directions in FIG. 5. The large area photodetector 503 and the high speed LED 505 are coupled to opposite ends of each fiber. Since the fiber diameter is relatively large, aligning each LED and photodetector to its associated fiber core is easy, enabling low-cost packaging. In some embodiments the fiber has a length between 10 and 300 meters. In some embodiments the fiber has a length of less than 10 meters. In some embodiments the fiber has a length between 1 and 5 meters.

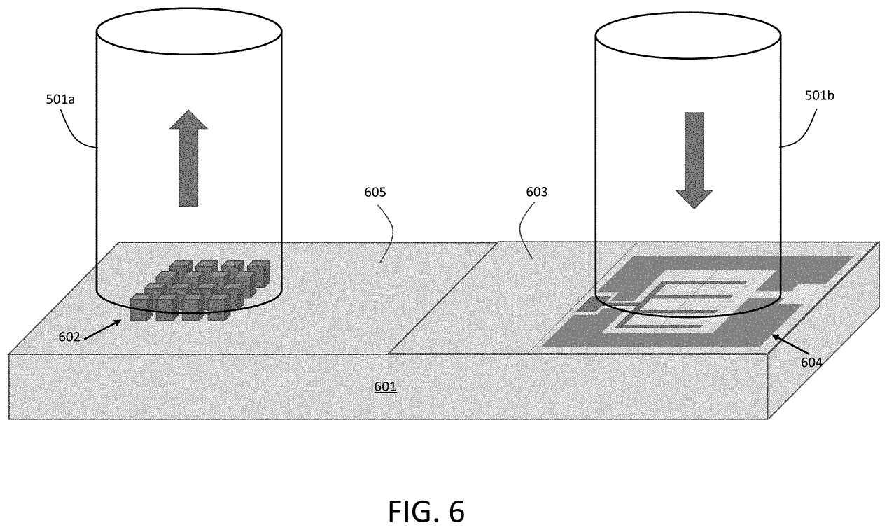

FIG. 6 shows a diagram of an example transceiver. In some embodiments, a photodetector 604 and an amplifier for amplifying electrical signals from the photodetector, together with an LED driver 605, are all fabricated in a single silicon substrate 601, and an LED or LED array 602 may be mounted on top of this substrate. The photodetector and the amplifier may be connected to a logic circuit 603 in the integrated circuit. A first plastic optical fiber 501a passes light emitted by the LED or LED array to a receiver, and a second plastic optical fiber 501b passes light to the photodetector. In some embodiments, and for example as illustrated in FIG. 6, rather than one large diameter microLED, multiple smaller LEDs are driven in parallel. For instance, rather than a single 80 um diameter LED, an array of 16 LEDs, each with a diameter of 20 microns, can be used, where they are all electrically connected in parallel. Such an array of smaller LEDs might be preferred as the devices can be more reliable and run cooler, among other reasons.

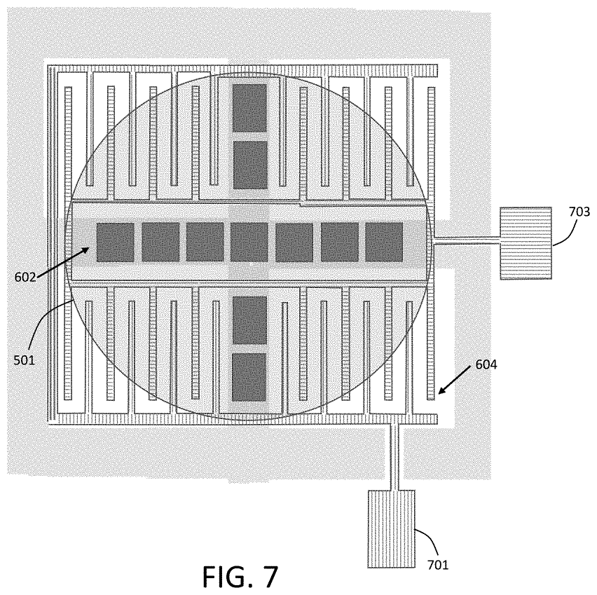

FIG. 7 shows a diagram with LEDs interspersed within a photodetector, allowing for a single fiber bidirectional link (half-duplex). In some embodiments, an array of LEDs is dispersed within a detector array. Such a configuration supports “half duplex” operation where a single fiber 501 carries data in both directions. In FIG. 7, 11 small microLEDs are placed within a photodetector. The photodetector may include a plurality of n-fingers and a plurality of p-fingers, for example as discussed with respect to FIGS. 4A-B. The n-fingers may be connected to an n-contact 701, and the p-fingers may be connected to a p-contact 703. In FIG. 7, the microLEDs are arranged in a form of a cross, that may be considered to split the photodetector into four sections. In some embodiments, the link is operated in half-duplex mode: when a transceiver is in receive mode, the light from the fiber is collected by the detectors when the LEDs are turned off, and the photodetectors receive a signal. When a transceiver is in transmit mode, the LEDs are turned on in parallel and light is transmitted into the fiber. However, light that falls on the LEDs when in receive mode may be wasted, and therefore the half-duplex embodiment may have lower sensitivity than dual fiber solutions.

Although the invention has been discussed with respect to various embodiments, it should be recognized that the invention comprises the novel and non-obvious claims supported by this disclosure.

What is claimed is:

1. An optical data link comprising:
an array of microLEDs, comprised of GaN, connected in parallel, for generating light, to carry data, in a wavelength range between 420 nm and 500 nm, inclusive, the microLEDs of the array of microLEDs having a 3 dB bandwidth greater than 1 Gb/s when driven with a current density of about 30 A/cm\hat{ }2;
a receiver including a photodetector with a lateral structure; and
a plastic optical fiber with a core diameter in the range of 100 μm-1000 μm for carrying the light to the receiver.

2. The optical link of claim 1, wherein the microLEDs each have a diameter of 20 microns or less.

3. The optical link of claim 1, wherein the lateral structure of the photodetector extends beyond the diameter of the core of the plastic optical fiber.

4. The optical link of claim 1, wherein the array of microLEDs are within an outline of a lateral structure of a further photodetector, and a further array of microLEDs are within an outline of the lateral structure of the photodetector, providing a duplex optical data link.

5. The optical link of claim 1, wherein the microLEDs include a n-region, a p-region, and a quantum well region between the n-region and the p-region, with a side of the quantum well region closest to the n-region p-doped.

6. The optical link of claim 1, further comprising a silicon substrate, driver circuitry for driving the array of microLEDs and wherein the receiver includes an amplifier for amplifying signals from the photodetector, with the driver circuitry, amplifier, and photodetector in the silicon substrate and the array of microLEDs on the silicon substrate.

7. The optical link of claim 6, wherein the receiver does not include equalization circuitry for processing of signals after reception from the plastic optical fiber.

8. The optical link of claim 1, wherein the plastic optical fiber has a length of less than 10 meters.

9. The optical link of claim 1, wherein the plastic optical fiber has a length between 1 and 5 meters.

10. An optical data link, comprising:
at least one microLED generating light in the visible spectrum;
a photodetector with a lateral structure for detecting the light; and
a plastic optical fiber with a core diameter in the range of 100 μm-1000 μm for passing the light from the at least one microLED to the photodetector.

11. The optical link of claim 10, wherein the at least one microLED is an array of microLEDs electrically connected to drive circuitry in parallel.

12. The optical link of claim 11, wherein the microLEDs include a p-region, an n-region, and a recombination region including quantum wells between the p-region and the n-region, with p-doping in the recombination region near the n-region.

13. The optical link of claim 12, wherein the microLEDs are comprised of GaN.

14. The optical link of claim 10, wherein the plastic optical fiber has a core diameter of about 0.50 mm.

15. The optical link of claim 10, wherein the plastic optical fiber has a core diameter between 0.4 and 0.5 mm.
